(19) United States
(12) Patent Application Publication
(10) Pub. No.: US 2025/0203843 A1
(43) Pub. Date: Jun. 19, 2025

(54) MEMORY DEVICE AND MANUFACTURING METHOD THEREOF

(71) Applicant: NANYA TECHNOLOGY CORPORATION, New Taipei city (TW)

(72) Inventors: Yao-Hsiung KUNG, Taoyuan City (TW); Chao-Wen LAY, New Taipei City (TW)

(21) Appl. No.: 18/540,989

(22) Filed: Dec. 15, 2023

(51) Int. Cl. H10B 12/00

(52) U.S. Cl. CPC H10B 12/0335; H10B 12/482

(57) ABSTRACT

A manufacturing method of a memory device includes forming bit line structures over a substrate, forming a conductive structure between and over the bit line structures, in which the conductive structure exposes a portion of the bit line structures, forming a spacer including an air gap along sidewalls of the bit line structures, and forming an isolation structure between the conductive structure and one of the bit line structures, in which the isolation structure includes a first insulation material layer sealing the air gap and a second insulation material layer over the first insulation material layer, and the first insulation material layer and the second insulation material layer are in contact with the one of the bit line structures.

### BACKGROUND

### Field of Disclosure

The present disclosure relates to a memory device and a manufacturing method thereof.

### Description of Related Art

A typical dynamic random access memory (DRAM) memory cell incorporates a capacitor and a transistor in which the capacitor temporarily store data based on the charged state of the capacitor. A bit line is electrically connected to a source region of the transistor, and a word line is electrically connected to a gate region of the transistor. As technology scaling, it needs the tight overlay control between different structures, such as the capacitors and the landing pads, to gain process integration margin. However, during forming the capacitors, the components adjacent to the landing pads may be accidentally damaged due to misalignment between the landing pads and trenches for the capacitors.

### SUMMARY

In some embodiments of the present disclosure, a manufacturing method of a memory device includes forming bit line structures over a substrate, forming a conductive structure between and over the bit line structures, in which the conductive structure exposes a portion of the bit line structures, forming a spacer including an air gap along sidewalls of the bit line structures, and forming an isolation structure between the conductive structure and one of the bit line structures, in which the isolation structure includes a first insulation material layer sealing the air gap and a second insulation material layer over the first insulation material layer, and the first insulation material layer and the second insulation material layer are in contact with the one of the bit line structures.

In some embodiments, forming the spacer including the air gap along the sidewalls of the bit line structures includes sequentially forming a first spacer layer, a sacrificial spacer layer and a second spacer layer along the sidewalls of the bit line structures before forming the conductive structure, and removing the second spacer layer after forming the conductive structure.

In some embodiments, forming a conductive structure between and over the bit line structures includes forming a first trench in portions of the substrate that are exposed through the bit line structures, forming a first conductive layer in the first trench, forming a second conductive layer over the first conductive layer, forming a barrier layer over the second conductive layer, forming a landing pad material layer overfilling the first trench, forming a second trench by removing a portion of the barrier layer, a portion of the landing pad material layer and a portion of the bit line structures.

In some embodiments, forming the isolation structure between the conductive structure and one of the bit line structures includes forming the first insulation material layer lining a top surface of the bit line structure, a top surface and a sidewall of the conductive structure, removing a vertical portion of the first insulation material layer, such that a horizontal portion of the first insulation material layer remains on the top surface of the bit line structure, and a curved portion of the first insulation material layer remains between the conductive structure and one of the bit line structures, forming the second insulation material layer overfilling between the conductive structure and one of the bit line structures, and performing a planarization process to remove an excess portion of the second insulation material layer and the horizontal portion of the first insulation material layer until the top surface of the conductive structure is exposed.

In some embodiments, after forming the first insulation material layer, a plasma treatment is performed to the first insulation material layer.

In some embodiments, the manufacturing method further includes forming a capacitor structure over the conductive structure and the isolation structure, in which a bottom electrode layer of the capacitor structure is in contact with the conductive structure.

In some embodiments, forming the capacitor structure over the conductive structure and the isolation structure includes sequentially forming a first support layer, a first sacrificial layer, a second support layer, a second sacrificial layer and a third support layer over the conductive structure and the isolation structure, forming a third trench penetrating the first support layer, the first sacrificial layer, the second support layer, the second sacrificial layer and the third support layer and exposing the conductive structure, forming the bottom electrode layer lining the third trench, removing the first sacrificial layer and the second sacrificial layer, forming a dielectric layer lining the bottom electrode layer, the first support layer, the second support layer and the third support layer, and filling a top electrode layer between the dielectric layer.

In some embodiments, the second insulation material layer of the isolation structure has a higher etching resistance to an etchant used during forming the third trench than the first insulation material layer of the isolation structure does.

In some embodiments, the first sacrificial layer and the second sacrificial layer are made of different material from the second insulation material layer of the isolation structure.

In some embodiments, a dielectric constant of the second insulation material layer of the isolation structure is lower than a dielectric constant of the first insulation material layer of the isolation structure.

In some embodiments of the present disclosure, a memory device includes a substrate, bit line structures, spacers, a conductive structure and an isolation structure. The bit line structures are over the substrate. The spacers are along sidewalls of the bit line structures, in which each of the spacers includes an air gap. The conductive structure is between the spacers. The isolation structure is between the conductive structure and one of the bit line structures, in which the isolation structure includes a first insulation material layer sealing the air gap and a second insulation material layer over the first insulation material layer, and the first insulation material layer and the second insulation material layer are in contact with the one of the bit line structures.

In some embodiments, the memory device further includes a capacitor structure over the conductive structure and the isolation structure, in which the capacitor structure includes a bottom electrode in contact with the conductive structure, a dielectric layer lining the bottom electrode, and a top electrode layer lining the dielectric layer.

In some embodiments, the bottom electrode of the capacitor structure is further in contact with the second insulation material layer of the isolation structure.

In some embodiments, the capacitor structure and the first insulation material layer of the isolation structure are separated by the second insulation material layer of the isolation structure.

In some embodiments, each of the spacers includes a first spacer layer in contact with one of the bit line structures, and a second spacer layer in contact with the conductive structure, in which the first spacer layer is separated from the second spacer layer by the air gap, and the second insulation material layer of the isolation structure is made of the different material from the first spacer layer and the second spacer layer.

In some embodiments, a dielectric constant of the second insulation material layer of the isolation structure is lower than a dielectric constant of the first insulation material layer of the isolation structure.

In some embodiments, the first insulation material layer of the isolation structure has a concave surface and a convex surface, and an intersection of the concave surface and the convex surface is in contact with one of the bit line structures.

In some embodiments, the first insulation material layer of the isolation structure has a concave surface and a convex surface, and an intersection of the concave surface and the convex surface is in contact with the conductive structure.

In some embodiments, the second insulation material layer of the isolation structure is in contact with the conductive structure.

In some embodiments, the second insulation material layer of the isolation structure and the spacer are separated by the first insulation material layer of the isolation structure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-17 illustrate cross-section views of a manufacturing process of a memory device, and FIG. 18 illustrates a circuit diagram of the memory device.

### DETAILED DESCRIPTION

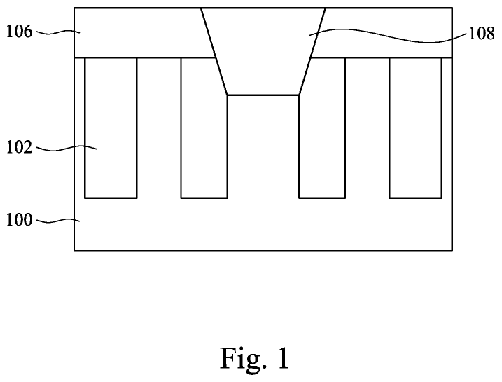

FIGS. 1-17 illustrate cross-section views of a manufacturing process of a memory device, and FIG. 18 illustrates a circuit diagram of the memory device. Referring to FIG. 18, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. A bit line BL is electrically connected to a source region of the transistor TR, and a word line WL is electrically connected to a gate region of the transistor TR. Ideally, the capacitor is electrically connected to the respective transistor by a conductive structure, and the bottom of the capacitor completely overlaps the top surface of the conductive structure to ensure maximum contact area. However, the trench for forming the capacitor may shift from the top surface of the conductive structure during forming the capacitor in some embodiments, and thus the trench may expose or further penetrate through the isolation structure adjacent to the conductive structure. Therefore, a memory device with the isolation structure having high resistance to the manufacturing process of the capacitor is provided in the present disclosure. In the present disclosure, we focus on the manufacturing process of the bit lines and the capacitors. The manufacturing process of the word lines and the transistors will not be mentioned in the present disclosure.

Referring to FIG. 1, a substrate 100 is provided. Isolation structures 102 are formed in the substrate 100 and define active regions in the substrate 100. A dielectric layer 106 is formed over the substrate 100 and the isolation structures 102. A polysilicon structure 108 is formed in the dielectric layer 106 and is in contact with the substrate 100. The substrate 100 may be a silicon substrate or other suitable semiconductor substrate. The isolation structures 102 may be made of silicon oxide, silicon nitride, or the like. The dielectric layer 106 may be made of silicon oxide, silicon nitride, or the like.

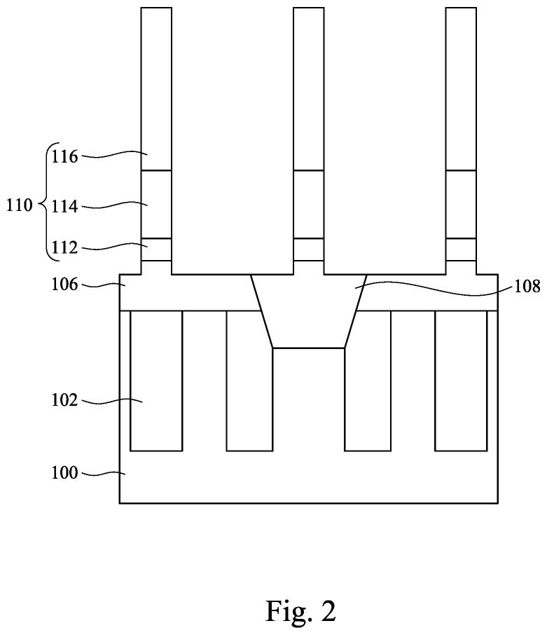

Referring to FIG. 2, bit line structures 110 are formed over the substrate 100. The bit line structures 110 include a silicide layer 112, a metal layer 114 over the silicide layer 112, and a hard mask layer 116 over the metal layer 114. The bit line structures 110 may be formed by, for example, sequentially forming a silicide material layer, a metal material layer, and a hard mask material layer over the substrate 100. Subsequently, the silicide material layer, the metal material layer, and the hard mask material layer are patterned into the silicide layer 112, the metal layer 114, and the hard mask layer 116, and the bit line structures 110 are formed.

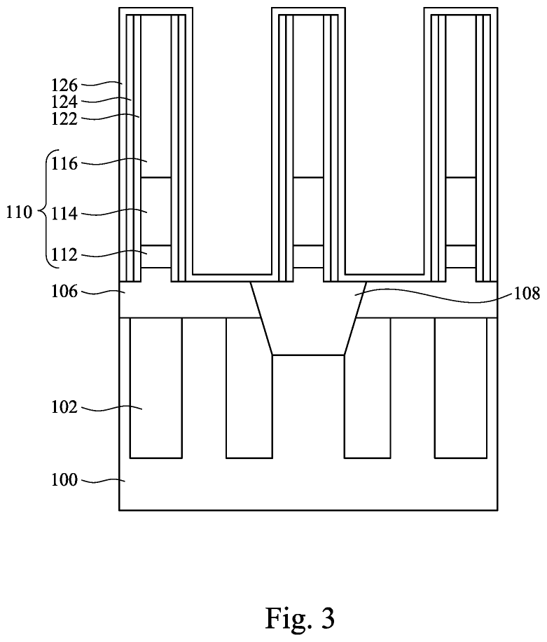

Referring to FIG. 3, first spacer layers 122, sacrificial spacer layers 124 and a second spacer layer 126 are sequentially formed along the sidewalls of the bit line structures 110. Specifically, a first spacer material layer is firstly formed conformal to the bit line structures 110 and the dielectric layer 106, then an anisotropic process is performed to remove a horizontal portion of the first spacer material layer, and the vertical portion of the first spacer material layer forms the first spacer layers 122 in contact with and lining the sidewalls of the bit line structures 110. Subsequently, a second spacer material layer is formed conformal to the first spacer layers 122, the bit line structures 110 and the dielectric layer 106, then an anisotropic process is performed to remove a horizontal portion of the second spacer material layer, and the vertical portion of the second spacer material layer forms the sacrificial spacer layers 124 in contact with and lining the first spacer layers 122. Subsequently, the second spacer layer 126 is formed conformal to the sacrificial spacer layers 124, the bit line structures 110 and the dielectric layer 106. The first spacer layers 122, the sacrificial spacer layers 124 and the second spacer layer 126 are made of dielectric material, such as silicon oxide, silicon nitride, or the like, and the sacrificial spacer layers 124 are made of different material from the first spacer layers 122 and the second spacer layers 126. For example, if the first spacer layers 122 and the second spacer layer 126 are made of silicon nitride, the sacrificial spacer layers 124 are made of silicon oxide.

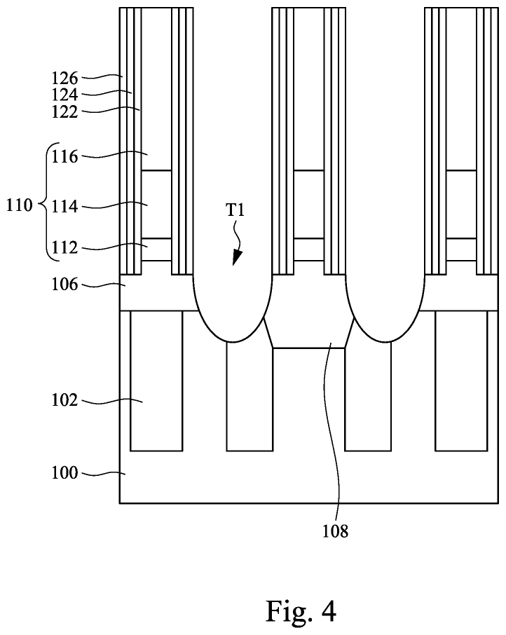

Referring to FIG. 4, trenches T1 are formed in portions of the substrate 100 that are exposed through the bit line structures 110. Specifically, the trenches T1 are formed by performing an etching process to penetrating through the second spacer layer 126 and the dielectric layer 106 to expose the substrate 100. During forming the trenches T1, the second spacer layer 126 over the bit line structures 110 are also removed, so the top surfaces of the bit line structures 110 are exposed.

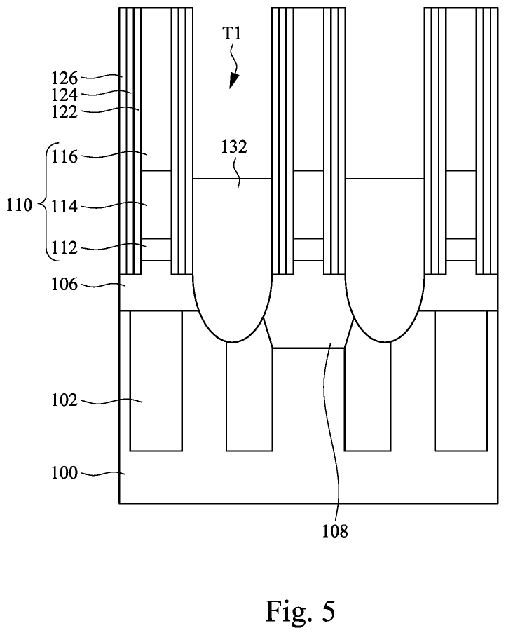

Referring to FIG. 5, first conductive layers 132 are formed in the trenches T1 between the bit line structures 110. Specifically, a first conductive material layer may be firstly formed overfilling in the trenches T1. Subsequently, a planarization process is performed to remove an excess portion of the first conductive material layer over the bit line structures 110 to expose the top surfaces of the bit line structures 110. Subsequently, the first conductive material layer is etched back to form the first conductive layers 132 in the trenches T1. In some embodiments, the first conductive layer 132 is made of doped polysilicon.

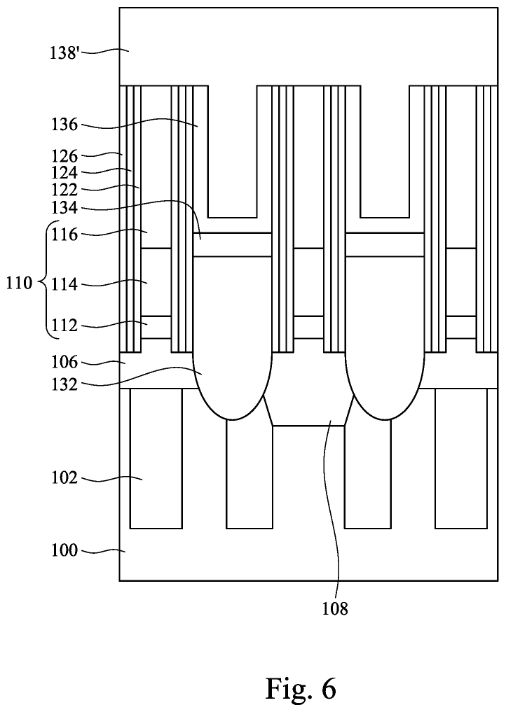

Referring to FIG. 6, second conductive layers 134 are formed over the first conductive layers 132, barrier layers 136 are formed over the second conductive layers 134, and a landing pad material layer 138′ is formed overfilling the trench T1 between the bit line structures 110. In some embodiments, the second conductive layers 134 may be formed by depositing a metal layer in contact with the top surfaces of the first conductive layers 132, and reacting the top surfaces of the first conductive layers 132 with the metal layer. In some other embodiments, the second conductive layers 134 may be formed by forming a second conductive material layer overfilling the trenches T1. Subsequently, a planarization process is performed to remove an excess portion of the second conductive material layer over the bit line structures 110 to expose the top surfaces of the bit line structures 110. Subsequently, the second conductive material layer is etched back to form the second conductive layers 134 in the trenches T1 and over the first conductive layers 132.

After forming the second conductive layers 134, the barrier layers 136 are formed over the second conductive layers 134. Specifically, a barrier material layer is firstly formed conformal to the bit line structures 110 and the second conductive layers 134. Subsequently, the barrier material layer over the bit line structures 110 is removed to expose the top surfaces of the bit line structures 110, and the remaining portion of the barrier material layer forms the barrier layers 136. After forming the barrier layers 136, the landing pad material layer 138′ is formed overfilling in the trench T1 between the bit line structures 110. In some embodiments, the second conductive layer 134 is made of metal silicide, the barrier layer 136 is made of TaN, TiN, but not limited thereto, and the landing pad material layer 138′ is made of Ti, TiN, Ta, TaN, W, Cu, Au, or alloys thereof, but not limited thereto.

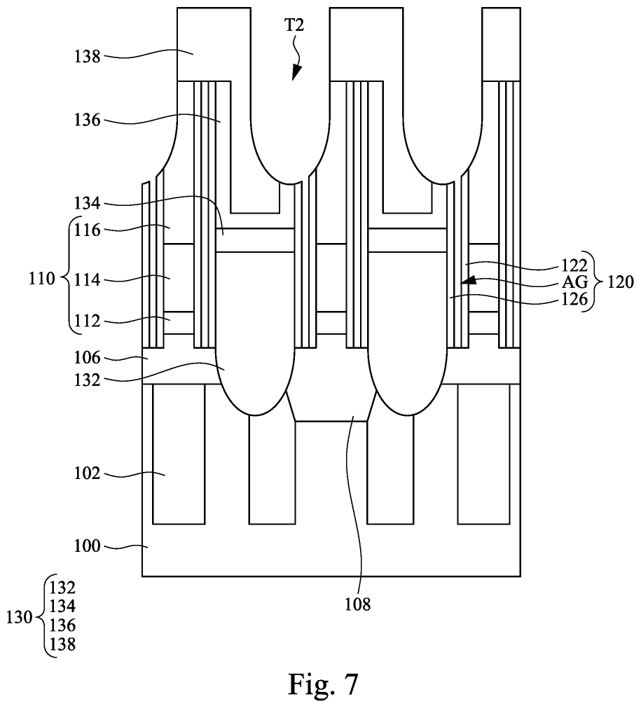

Referring to FIG. 7, trenches T2 are formed by removing a portion of the barrier layer 136, a portion of the landing pad material layer 138′ and a portion of the bit line structures 110. After forming the trenches T2, a remaining portion of the landing pad material layer 138′ forms landing pads 138 extending from over the barrier layers 136 to over the bit line structures 110. A first conductive layer 132, a second conductive layer 134, a barrier layer 136, and a landing pad 138 stacked vertically may be collectively referred to as a conductive structure 130. That is, after forming the trenches T2, the conductive structures 130 between and over the bit line structures 110 are formed, and the conductive structures 130 may serve as the cell contact connecting the active regions in the substrate 100 and the capacitor structure formed subsequently. The trenches T2 may be formed by performing an etching process to expose the sacrificial spacer layers 124 (FIG. 6), and then the sacrificial spacer layers 124 are removed to form air gaps AG between the first spacer layers 122 and the second spacer layers 126. Therefore, spacers 120 including the first spacer layers 122, the second spacer layers 126 and the air gaps AG are formed along sidewalls of the bit line structures 110. The first spacer layers 122 are in contact with the bit line structures 110. The second spacer layers 126 are in contact with the conductive structures 130, and the first spacer layers 122 are separated from the second spacer layers 126 by the air gaps AG. In some embodiments, the sacrificial spacer layers 124 may be removed by performing a wet etching process.

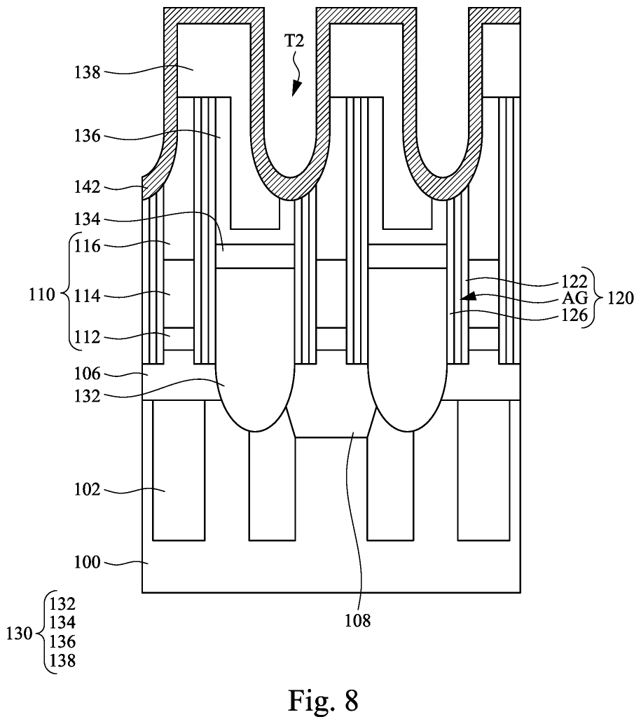

Referring to FIG. 8, a first insulation material layer 142 is formed lining the top surface of the bit line structures 110, a top surface and a sidewall of the conductive structures 130. The first insulation material layer 142 is used to seals the air gaps AG. The manufacturing process and the material of the first insulation material layer 142 are selected to allow the first insulation material layer 142 seals the air gaps AG but not flow into the air gaps AG. In some embodiments, the first insulation material layer 142 is formed by performing a plasma enhanced atomic layer deposition (PEALD) process. In some embodiments, the first insulation material layer 142 is made of any suitable dielectric material, such as silicon oxide, silicon nitride, and the like. In some embodiments, the first insulation material layer 142 is made of the same material from the first spacer layers 122 and the second spacer layers 126.

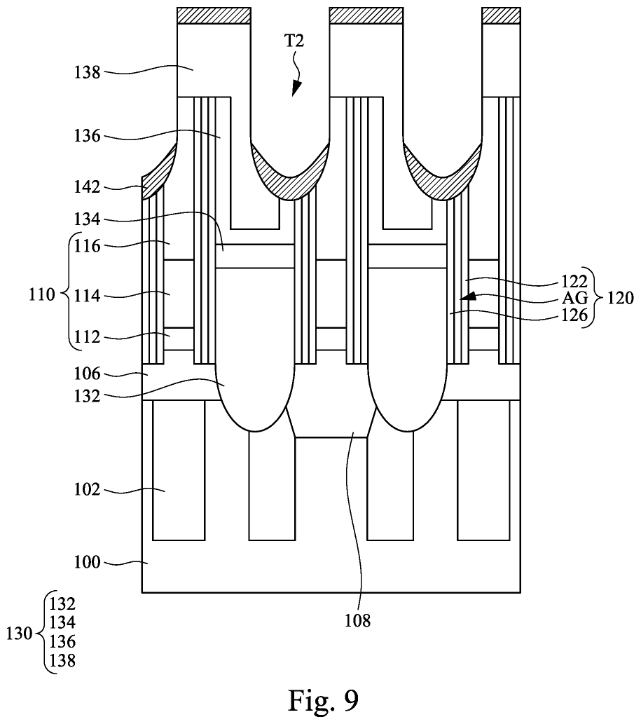

After forming the first insulation material layer 142, a plasma treatment is performed to the first insulation material layer 142. The plasma treatment is used to create etching selectivity between the vertical portion, the horizontal portion and the curved portion of the first insulation material layer 142. The vertical portion of the first insulation material layer 142 is referred to as the first insulation material layer 142 lining the vertical sidewalls of the conductive structures 130 and the bit line structures 110. The horizontal portion of the first insulation material layer 142 is referred to as the first insulation material layer 142 over the top surfaces of the bit line structures 110. The curved portion of the first insulation material layer 142 is referred to as the first insulation material layer 142 at the bottom of the trenches T2. After the plasma treatment, the vertical portion of the first insulation material layer 142 has a higher etching resistance to certain etchant (such as the etchant used in FIG. 9) than the horizontal portion and the curved portion of the first insulation material layer 142 do.

Referring to FIG. 9, the vertical portion of the first insulation material layer 142 is removed, such that the horizontal portion of the first insulation material layer 142 remains on the top surface of the bit line structures 110, and the curved portion of the first insulation material layer 142 remains between the conductive structures 130 and the bit line structures 110. In some embodiments, an etching process is performed to remove the vertical portion of the first insulation material layer 142, and the etchant may be diluted hydrofluoric acid. After removing the vertical portion of the first insulation material layer 142, the curved portion of the first insulation material layer 142 still seals the air gaps AG.

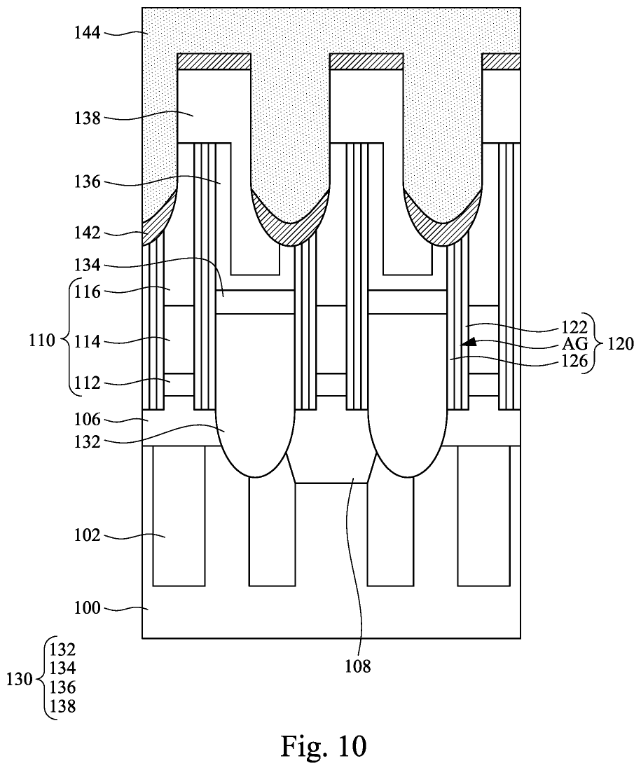

Referring to FIG. 10, a second insulation material layer 144 is formed overfilling between the conductive structures 130 and the bit line structure 110. The second insulation material layer 144 is made of different material from the first insulation material layer 142, and a dielectric constant of the second insulation material layer 144 is lower than a dielectric constant of the first insulation material layer 142. The second insulation material layer 144 of the isolation structure 140 is also made of the different material from the first spacer layers 122 and the second spacer layers 126. In some embodiments, the second insulation material layer 144 is SiCO or SiCON, but the present disclosure is not limited thereto.

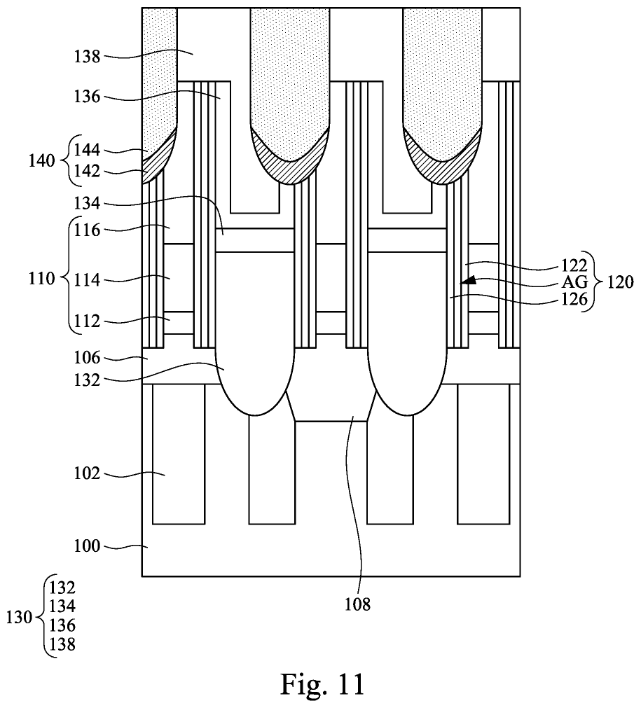

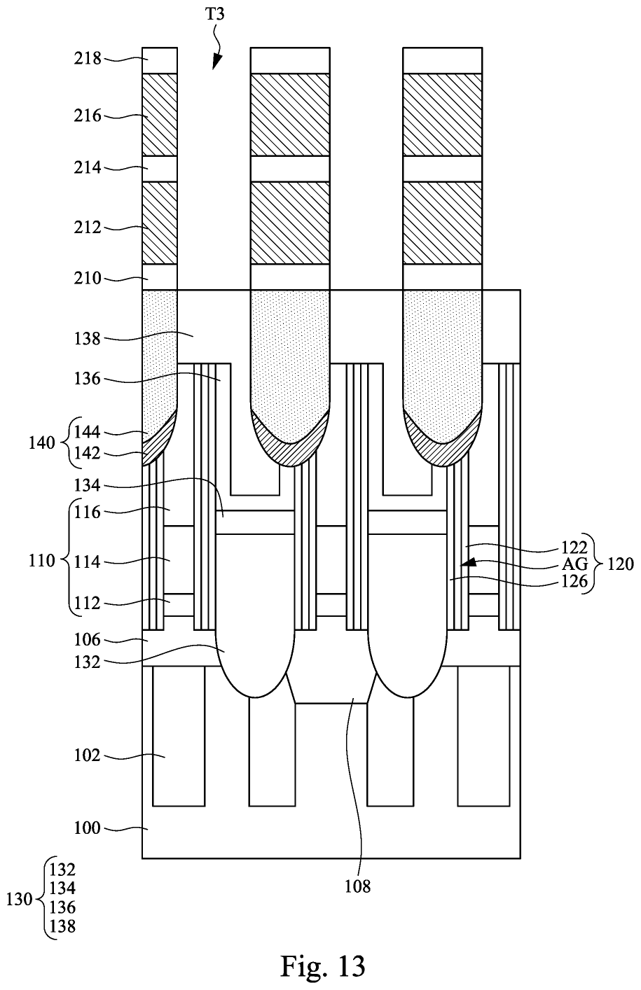

Referring to FIG. 11, a planarization process is performed to remove an excess portion of the second insulation material layer 144 and the horizontal portion of the first insulation material layer 142 until the top surfaces of the conductive structures 130 are exposed. As such, the second insulation material layers 144 fill the trenches T2 and completely cover the curved portion of the first insulation material layer 142, and isolation structures 140 between the conductive structures 130 and the bit line structures 110 are formed. Each of the isolation structures 140 includes a first insulation material layer 142 sealing the air gap AG and a second insulation material layer 144 over the first insulation material layer 142, and the first insulation material layer 142 and the second insulation material layer 144 are in contact with the bit line structures 110. The second insulation material layer 144 of the isolation structure 140 and the spacer 120 are separated by the first insulation material layer 142 of the isolation structure 140. The isolation structures 140 are used to provide electrical isolation between the conductive structures 130 and prevent the subsequent process (such as the process in FIG. 13) from punching through the air gaps AG. The mechanism of how the isolation structures 140 prevent the subsequent process (such as the process in FIG. 13) from punching through the air gaps AG will be discussed in FIG. 13.

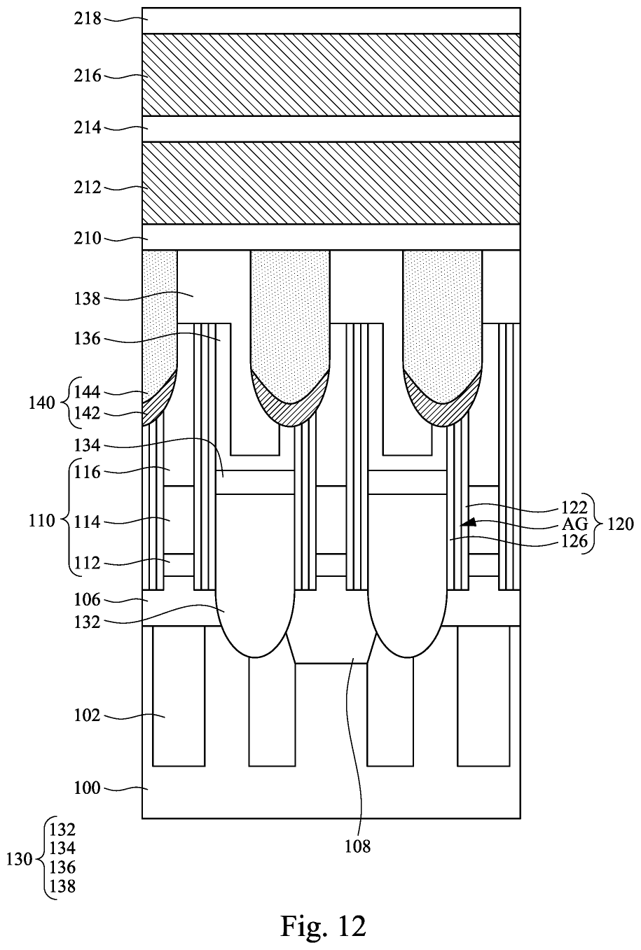

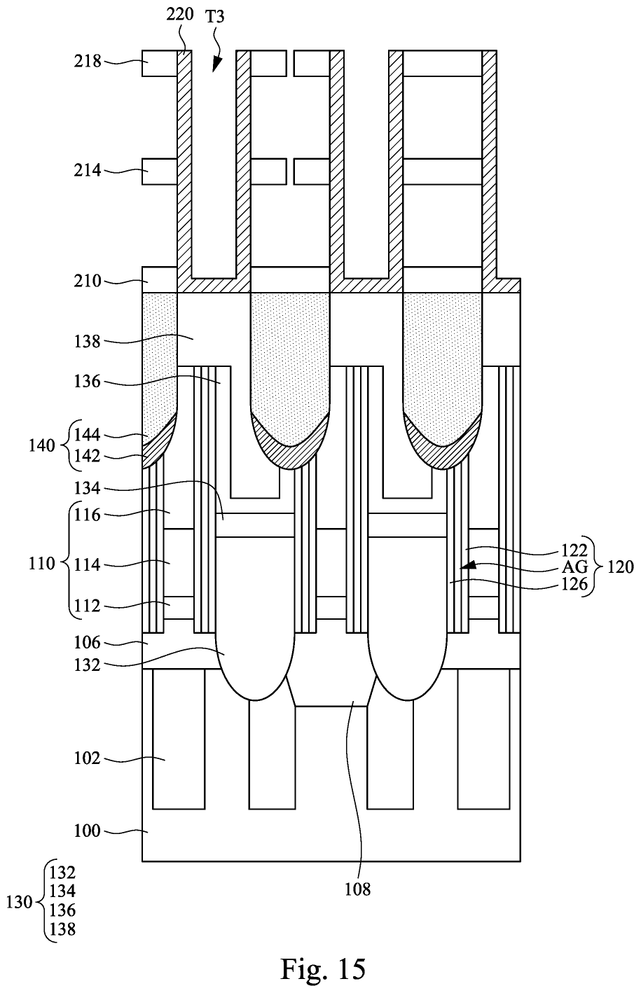

Referring to FIG. 12, a first support layer 210, a first sacrificial layer 212, a second support layer 214, a second sacrificial layer 216 and a third support layer 218 are sequentially formed over the conductive structures 130 and the isolation structure 140. In some embodiments, the first support layer 210, the second support layer 214 and the third support layer 218 are made of dielectric materials, such as silicon nitride. The first sacrificial layer 212 and the second sacrificial layer 216 are made of dielectric materials different from the first support layer 210, the second support layer 214 and the third support layer 218. The first sacrificial layer 212 and the second sacrificial layer 216 may be made of silicon oxide. Moreover, the first sacrificial layer 212 and the second sacrificial layer 216 are made of different material from the second insulation material layer 144 of the isolation structures 140. Therefore, the second insulation material layer 144 of the isolation structures 140 keep intact after removing the first sacrificial layer 212 and the second sacrificial layer 216 in the subsequent process (such as process in FIG. 15).

Referring to FIG. 13, trenches T3 penetrating the first support layer 210, the first sacrificial layer 212, the second support layer 214, the second sacrificial layer 216 and the third support layer 218 are formed and expose the conductive structures 130. In some embodiments, the trenches T3 may be formed by performing one or more etching processes. During forming the trenches T3, the isolation structures 140 are used to prevent the process in FIG. 13 from punching through the air gaps AG. Specifically, at the ideal situation, the trenches T3 completely overlap the top surfaces of the conductive structures 130, and do not expose the isolation structures 140. Therefore, the bottom electrode layers formed in trenches T3 in the subsequent process and the conductive structures 130 have maximum contact area, as shown in FIG. 13. However, in some embodiments, the trenches T3 may be misaligned with the top surfaces of the conductive structures 130, and thus the trenches T3 may expose a portion of the isolation structures 140. The second insulation material layer 144 of the isolation structure 140 has a higher etching resistance to an etchant used during forming the trenches T3 than the first insulation material layer 142 of the isolation structure 140 does. Therefore, even if the isolation structures 140 are exposed during forming the trenches T3, the second insulation material layer 144 of the isolation structure 140 may prevent the process in FIG. 13 from further punching through the isolation structure 140, which may lead to the exposure of the air gaps AG. The bottom electrode layer 220 may fill the air gaps AG and cause electrical short between the capacitor structure formed subsequently and the bit line structures 110.

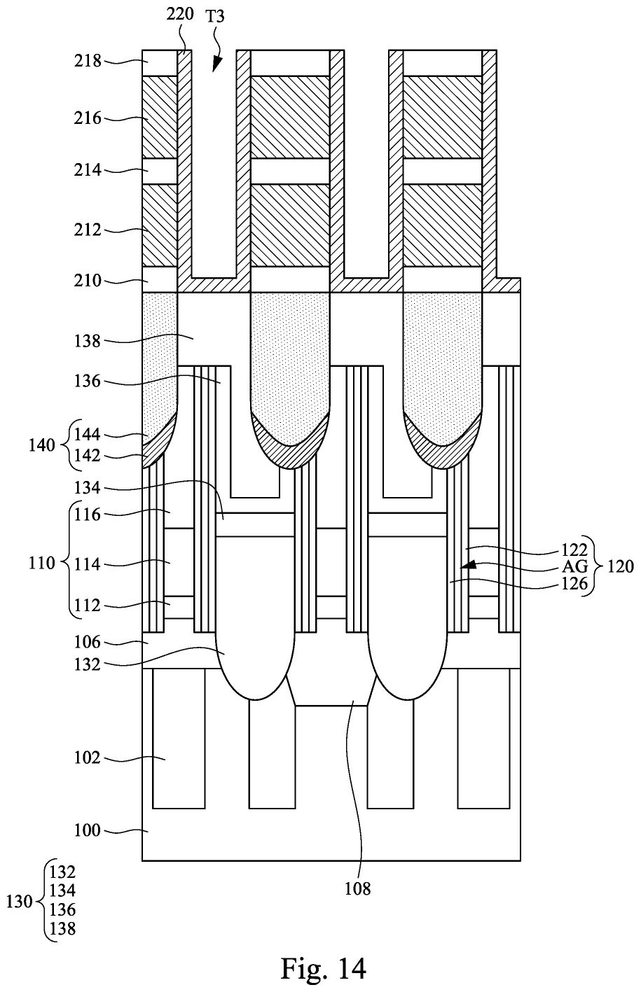

Referring to FIG. 14, bottom electrode layers 220 lining the trenches T3 are formed. In some embodiments, a bottom electrode material layer is first formed lining the trenches T3 and over the third support layer 218. Subsequently, the bottom electrode material layer over the third support layer 218 is removed by performing, for example, a planarization process. The remaining portion of the bottom electrode material layer forms the bottom electrode layers 220 lining the trenches T3. In some embodiments, the bottom electrode layers 220 may be made of metals, metal compounds, alloy compounds, other conductive materials or combinations thereof, such as titanium nitride or silicon-doped titanium nitride.

Referring to FIG. 15, the first sacrificial layer 212 and the second sacrificial layer 216 are removed. Specifically, removing the first sacrificial layer 212 and the second sacrificial layer 216 includes forming a hole in some of the third support layer 218 until the top surface of the second sacrificial layer 216 is exposed. Subsequently, the second sacrificial layer 216 is removed through the hole by performing a wet etching process. After the second sacrificial layer 216 is removed, a hole in some of the second support layer 214 is formed until the top surface of the first sacrificial layer 212 is exposed, and then the first sacrificial layer 212 is removed through the hole by performing a wet etching process. As such, the first support layer 210, the second support layer 214, the third support layer 218 and the bottom electrode layers 220 are still in place.

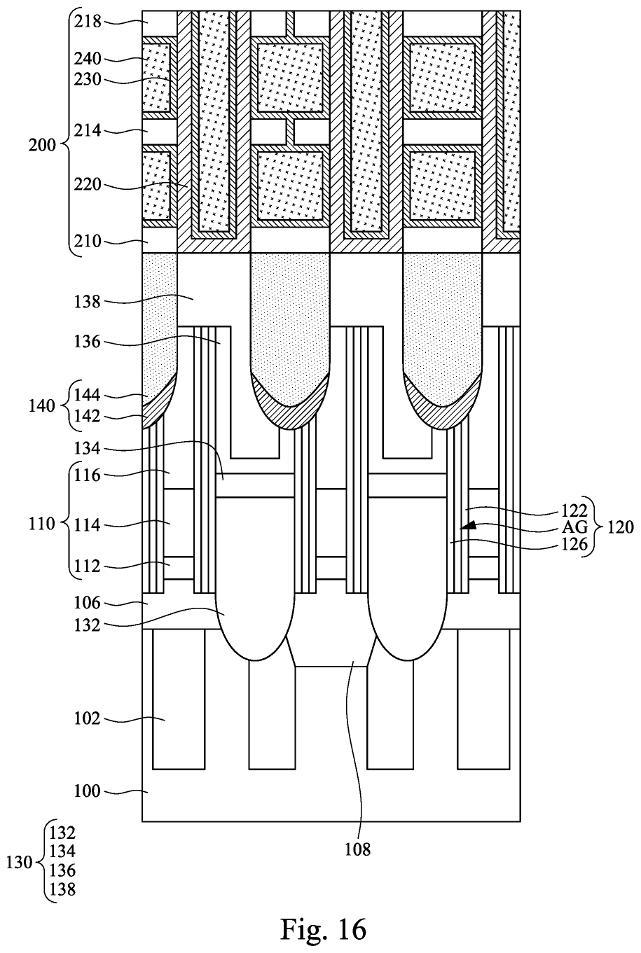

Referring to FIG. 16, dielectric layers 230 lining the bottom electrode layers 220, the first support layer 210, the second support layer 214 and the third support layer 218 are formed, and the top electrode layers 240 are formed between the dielectric layers 230. In some embodiments, the dielectric layers 230 may be made of high-k dielectric material, such as ZrO₂, and the top electrode layers 240 may be made of metals, metal compounds, alloy compounds, other conductive materials or combinations thereof, such as titanium nitride or silicon-doped titanium nitride. As such, a capacitor structure 200 is formed over the conductive structures 130 and the isolation structures 140. The bottom electrode layers 220 of the capacitor structure 200 are in contact with the conductive structures 130. The dielectric layer 230 is lining the bottom electrode layers 220, and the top electrode layer 240 is lining the dielectric layer 230.

The resulting memory device is shown in FIG. 16. The resulting memory device includes the substrate 100, the bit line structures 110, the spacers 120, the conductive structures 130, the isolation structures 140 and the capacitor structure 200. The bit line structures 110 are over the substrate 100. The spacers 120 are along the sidewalls of the bit line structures 110, and each of the spacers 120 includes an air gap AG. The conductive structures 130 are between the spacers 120. The isolation structures 140 are between the conductive structures 130 and the bit line structures 110. The capacitor structure 200 is over the conductive structures 130 and the isolation structures 140.

Each of the isolation structures 140 includes a first insulation material layer 142 sealing the air gap AG and a second insulation material layer 144 over the first insulation material layer 142, and the first insulation material layer 142 and the second insulation material layer 144 are in contact with the bit line structures 110. The first insulation material layer 142 of the isolation structure 140 has a concave surface and a convex surface, and an intersection of the concave surface and the convex surface is in contact with the bit line structure 110 and the conductive structure 130. The second insulation material layer 144 of the isolation structure 140 is also in contact with the bit line structure 110 and the conductive structure 130. That is, the second insulation material layer 144 may completely covers the first insulation material layer 142, and the first insulation material layer 142 and the capacitor structure 200 are separated by the second insulation material layer 144. The dielectric constant of the second insulation material layer 144 is lower than the dielectric constant of the first insulation material layer 142. Therefore, the second insulation material layer 144 of the isolation structures 140 may be used to prevent electrical short between the capacitor structure 200 and the bit line structures 110.

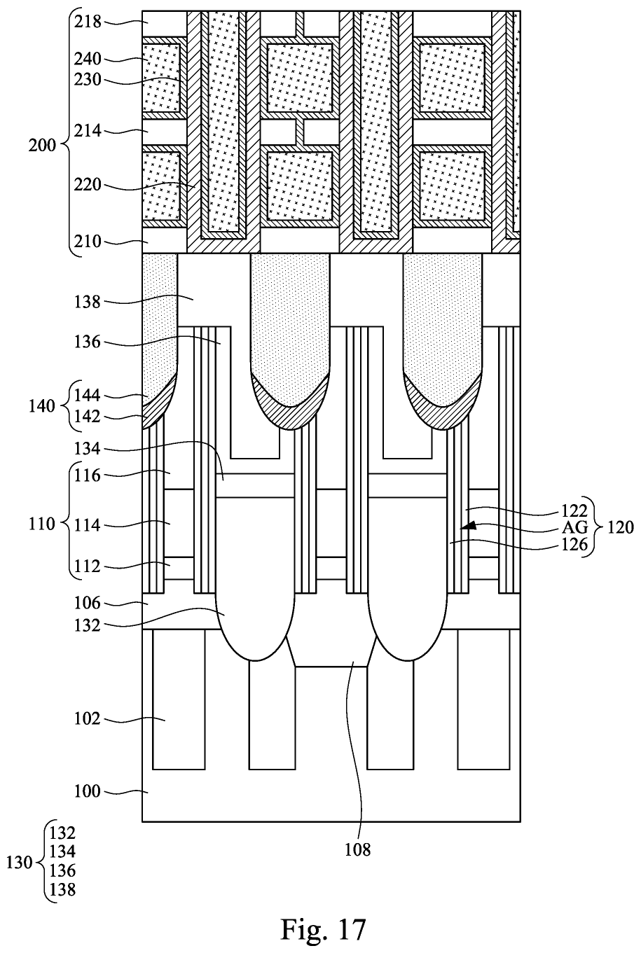

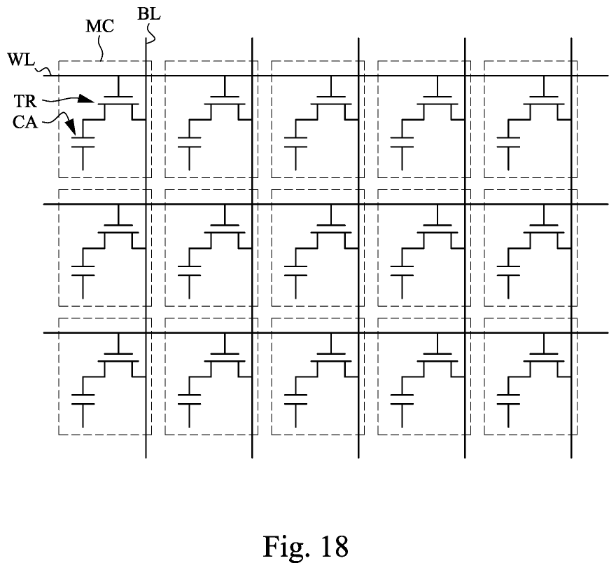

The second insulation material layer 144 is also used to prevent the process of manufacturing the capacitor structure 200 from punching through the isolation structure 140 if the capacitor structure 200 shifts from the top surface of the isolation structure 140, as shown in FIG. 17. In FIG. 17, the trenches for forming the bottom electrode layer 220 (such as trenches T3 in FIG. 13) shift from the top surfaces of the isolation structures 140 due to misalignment. As mentioned before, the second insulation material layer 144 is made of the material having high etching resistance to the etchant used for forming the trenches for forming the bottom electrode layer 220. Therefore, the second insulation material layer 144 serves as the etch stop layer, and the air gaps AG below are still sealed after forming the capacitor structure 200. The resulting bottom electrode layers 220 also shift from the top surface of the isolation structure 140 and are in contact with the isolation structures 140. If the second insulation material layer 144 having lower dielectric constant and higher etching resistance to the etchant mentioned in FIG. 13 is not presented, the air gaps AG are opened up if the trenches for forming the bottom electrode layer 220 (such as trenches T3 in FIG. 13) shift from the top surfaces of the isolation structures 140. The bottom electrode layer 220 may fill the air gaps AG and cause electrical short between the capacitor structure 200 and the bit line structures 110.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming bit line structures over a substrate;
forming a conductive structure between and over the bit line structures, wherein the conductive structure exposes a portion of the bit line structures;
forming a spacer comprising an air gap along sidewalls of the bit line structures; and
forming an isolation structure between the conductive structure and one of the bit line structures, wherein the isolation structure comprises a first insulation material layer sealing the air gap and a second insulation material layer over the first insulation material layer, and the first insulation material layer and the second insulation material layer are in contact with the one of the bit line structures.

2. The manufacturing method of claim 1, wherein forming the spacer comprising the air gap along the sidewalls of the bit line structures comprising:
sequentially forming a first spacer layer, a sacrificial spacer layer and a second spacer layer along the sidewalls of the bit line structures before forming the conductive structure; and
removing the second spacer layer after forming the conductive structure.

3. The manufacturing method of claim 1, wherein forming a conductive structure between and over the bit line structures comprises:
forming a first trench in portions of the substrate that are exposed through the bit line structures;
forming a first conductive layer in the first trench;
forming a second conductive layer over the first conductive layer;
forming a barrier layer over the second conductive layer;
forming a landing pad material layer overfilling the first trench; and
forming a second trench by removing a portion of the barrier layer, a portion of the landing pad material layer and a portion of the bit line structures.

4. The manufacturing method of claim 1, wherein forming the isolation structure between the conductive structure and one of the bit line structures comprises:
forming the first insulation material layer lining a top surface of the bit line structures, a top surface and a sidewall of the conductive structure;
removing a vertical portion of the first insulation material layer, such that a horizontal portion of the first insulation material layer remains on the top surface of the bit line structures, and a curved portion of the first insulation material layer remains between the conductive structure and one of the bit line structures;
forming the second insulation material layer overfilling between the conductive structure and one of the bit line structures; and
performing a planarization process to remove an excess portion of the second insulation material layer and the horizontal portion of the first insulation material layer until the top surface of the conductive structure is exposed.

5. The manufacturing method of claim 4, wherein after forming the first insulation material layer, a plasma treatment is performed to the first insulation material layer.

6. The manufacturing method of claim 4, further comprising:
forming a capacitor structure over the conductive structure and the isolation structure, wherein a bottom electrode layer of the capacitor structure is in contact with the conductive structure.

7. The manufacturing method of claim 6, wherein forming the capacitor structure over the conductive structure and the isolation structure comprises:
sequentially forming a first support layer, a first sacrificial layer, a second support layer, a second sacrificial layer and a third support layer over the conductive structure and the isolation structure;
forming a third trench penetrating the first support layer, the first sacrificial layer, the second support layer, the second sacrificial layer and the third support layer and exposing the conductive structure;
forming the bottom electrode layer lining the third trench;
removing the first sacrificial layer and the second sacrificial layer;
forming a dielectric layer lining the bottom electrode layer, the first support layer, the second support layer and the third support layer; and
filling a top electrode layer between the dielectric layer.

8. The manufacturing method of claim 7, wherein the second insulation material layer of the isolation structure has a higher etching resistance to an etchant used during forming the third trench than the first insulation material layer of the isolation structure does.

9. The manufacturing method of claim 7, wherein the first sacrificial layer and the second sacrificial layer are made of different material from the second insulation material layer of the isolation structure.

10. The manufacturing method of claim 1, wherein a dielectric constant of the second insulation material layer of the isolation structure is lower than a dielectric constant of the first insulation material layer of the isolation structure.

11. A memory device, comprising:
a substrate;
bit line structures over the substrate,
spacers along sidewalls of the bit line structures, wherein each of the spacers comprises an air gap;
a conductive structure between the spacers; and
an isolation structure between the conductive structure and one of the bit line structures, wherein the isolation structure comprises a first insulation material layer sealing the air gap and a second insulation material layer over the first insulation material layer, and the first insulation material layer and the second insulation material layer are in contact with the one of the bit line structures.

12. The memory device of claim 11, further comprising:
a capacitor structure over the conductive structure and the isolation structure, wherein the capacitor structure comprises:
a bottom electrode in contact with the conductive structure;
a dielectric layer lining the bottom electrode; and
a top electrode layer lining the dielectric layer.

13. The memory device of claim 12, wherein the bottom electrode of the capacitor structure is further in contact with the second insulation material layer of the isolation structure.

14. The memory device of claim 12, wherein the capacitor structure and the first insulation material layer of the isolation structure are separated by the second insulation material layer of the isolation structure.

15. The memory device of claim 11, wherein each of the spacers comprises:
a first spacer layer in contact with one of the bit line structures; and
a second spacer layer in contact with the conductive structure, wherein first spacer layer is separated from the second spacer layer by the air gap, and the second insulation material layer of the isolation structure is made of a different material from the first spacer layer and the second spacer layer.

16. The memory device of claim 11, wherein a dielectric constant of the second insulation material layer of the isolation structure is lower than a dielectric constant of the first insulation material layer of the isolation structure.

17. The memory device of claim 11, wherein the first insulation material layer of the isolation structure has a concave surface and a convex surface, and an intersection of the concave surface and the convex surface is in contact with one of the bit line structures.

18. The memory device of claim 11, wherein the first insulation material layer of the isolation structure has a concave surface and a convex surface, and an intersection of the concave surface and the convex surface is in contact with the conductive structure.

19. The memory device of claim 11, wherein the second insulation material layer of the isolation structure is in contact with the conductive structure.

20. The memory device of claim 11, wherein the second insulation material layer of the isolation structure and the spacers are separated by the first insulation material layer of the isolation structure.
